(19) United States
(12) Patent Application Publication
(10) Pub. No.: US 2011/0025340 A1
(43) Pub. Date: Feb. 3, 2011

(54) SEMICONDUCTOR DEVICE ANALYZER AND SEMICONDUCTOR DEVICE ANALYSIS METHOD

(75) Inventors: Toyokazu NAKAMURA, Kanagawa (JP); Sumio Kuwabara, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/842,664

(22) Filed: Jul. 23, 2010

(30) Foreign Application Priority Data
Aug. 3, 2009 (JP) 2009-180922

(51) Int. Cl. G01R 31/307; H01J 37/28

(52) U.S. Cl. 324/501; 250/310; 250/307

(57) ABSTRACT

A semiconductor device analyzer comprises a function of radiating a charged particle beam on a sample and displaying a detected secondary electron image according to detected secondary electron intensity. A charged particle beam is radiated according to a first radiation pattern onto a semiconductor device that is to be analyzed, and a charge is injected. Next, a charge accumulation state of the semiconductor device that is to be analyzed is observed. A location where the charge accumulation state is abnormal can be detected as a defect location in the semiconductor device. A defect location is identified easily.

### TECHNICAL FIELD

### Reference to Related Application

This application is based upon and claims the benefit of the priority of Japanese patent application No. 2009-180922, filed on Aug. 3, 2009 the disclosure of which is incorporated herein in its entirety by reference thereto.

This invention relates to a semiconductor device analyzer and a semiconductor device analysis method, and in particular relates to a semiconductor device analyzer provided with a blanking mechanism and with a function of selectively radiating a charged particle beam on a sample and displaying a secondary electron image according to secondary electron intensity, and relates to a semiconductor device analysis method.

### BACKGROUND

It is known that, by using a Scanning Electron Microscope (referred to below as SEM), or a Focused Ion Beam (FIB), when a primary electron beam from an electron gun is radiated onto a semiconductor device that is to be analyzed, by observing a secondary electron image obtained by performing brightness conversion with regard to secondary electron intensity that has been detected, it is possible to detect an electrical defect or a defect that is hard to see from the surface of the semiconductor device. For example, in Patent Document 1 there is a proposal of a die-die test comparing images derived from dies respectively, and a die database test comparing an image derived from a die and an image (pseudo non-defective image) generated by an image simulator obtained by inputting CAD data of the die in question.

Patent Document 2 discloses a CAD tool that can collect abnormal reaction information obtained by a physical analysis of a semiconductor device, extract duplicate locations thereof, check with layout data, and estimate wiring suspected of failure or defect locations.

Patent Document 3 discloses a method of radiating an electron beam on a TEG (Test Element Group) for a contact short check, obtaining potential contrast of adjacent contact cells, setting a threshold for defect determination from a two dimensional histogram of respective signal intensities, and identifying a short detect and coordinates thereof.

Patent Document 4 discloses a method, with regard to SEM observation, of detecting a breakage defect in a wiring system of a lower layer without removing upper layer wiring, by increasing acceleration voltage of a radiated electron beam.

Patent Documents 5 and 6 disclose a method of performing charge elimination of a charged-up sample, by adjustment of acceleration voltage of a radiated electron beam.

### [Patent Document 1]

JP Patent Kokai Publication No. JP-A-5-258703

### [Patent Document 2]

JP Patent Kokai Publication No. JP-P2003-86689A

### [Patent Document 3]

JP Patent Kokai Publication No. JP-P2007-281136A

### [Patent Document 4]

JP Patent Kokai Publication No. JP-P2003-66117A

### [Patent Document 5]

JP Patent Kokai Publication No. JP-A-7-14537

### [Patent Document 6]

JP Patent Kokai Publication No. JP-P2003-303568A

### SUMMARY

The entire disclosures of Patent Documents 1 to 6 are incorporated herein by reference thereto. The following analyses are given by the present invention. FIG. 12 is a drawing showing an outline of a die database test of Patent Document 1. As shown in FIG. 12, with the progress of miniaturization of semiconductor devices, generally in a secondary election image observed by a SEM or the like, edges of an image pattern are rounded due to the influence of the resolution thereof (refer to (A), (B), and (C) in the lower left of FIG. 12). In contrast to this, with a pseudo non-defective image as a target for comparison, there is a problem in that there is no rounding of edges due to being faithfully created from design data (refer to (a), (b), and (c) in the lower right of FIG. 12), and it is difficult to compare the two. Furthermore, scale unit of the secondary electron image is different from that of the abovementioned pseudo non-defective image, and coloration of potential distribution shown in the abovementioned pseudo non-defective image is different from the intensity indicating the potential of the secondary electron image, so that the abovementioned comparison is even more difficult. Furthermore, in the method of Patent Document 1, the intensities of plural wiring layers in a semiconductor device may be mixed, offering difficulty in detecting change in the intensity of defect locations.

Furthermore, it may be desired to focus on a particular wiring system in the semiconductor device to observe an open (break) or a short. For example, in a method described in Patent Document 4, it is possible to radiate a temporary electron beam onto wiring of a lower layer, and to detect the presence or absence of a wire breakage in a stratum in question, but there is a problem in that it is not possible to detect locations where the electron beam is not radiated, nor the presence or absence of a wiring breakage in another layer that should be connected to the lower layer wiring in question.

According to a first aspect of the present invention there is provided a semiconductor device analyzer that radiates a charged particle beam on a sample and displays a secondary electron image according to detected secondary electron intensity. The semiconductor device analyzer comprises a unit that radiates a charged particle beam according to a first radiation pattern by which a charge is injected at a prescribed location on a semiconductor device that is to be analyzed, and injects the charge; and a unit that observes a charge accumulation state of the semiconductor device that is to be analyzed.

According to a second aspect of the present invention, there is provided a semiconductor device analysis method that uses a semiconductor device analyzer, which radiates a charged particle beam on a sample and displays a secondary electron image according to detected secondary electron intensity. The method comprises: injecting a charge by radiating a charged particle beam according to a first radiation pattern by which a charge is injected at a prescribed location of a semiconductor device that is to be analyzed; and observing a charge accumulation state of the semiconductor device that is to be analyzed.

The meritorious effects of the present invention are summarized as follows. According to the present invention, it is possible to observe presence or absence of a defect focusing on a particular location, based on design data of the semiconductor device. A reason for this is that a configuration is adopted in which a charge is injected at a targeted location of the semiconductor device, and the charge accumulation state expected by the injection of the charge is observed (scanned).

### BRIEF DESCRIPTION OF THE DRAWINGS

FIG. 1 is a block diagram showing a configuration of a semiconductor device analyzer according to a first exemplary embodiment of the present invention.

FIG. 2 is a drawing for describing defect detection flow (non-defective product) by the semiconductor device analyzer according to the first exemplary embodiment of the present invention.

FIG. 3 is a drawing showing a charge injection location according to a first radiation pattern.

FIG. 4 is a drawing showing observation locations according to a second radiation pattern.

FIG. 5 is a drawing showing observation locations according to a second radiation pattern different from FIG. 4.

FIG. 6 is a drawing for describing defect (defective product) detection flow by the semiconductor device analyzer according to the first exemplary embodiment of the present invention.

FIG. 7 is a drawing showing a charge injection location according to an example of a first radiation pattern.

FIG. 8 is a drawing showing observation locations according to an example of a second radiation pattern.

FIG. 9 is a drawing showing observation locations according to an example of a second radiation pattern different from FIG. 8.

FIG. 10 is a drawing showing observation locations according to an example of a second radiation pattern different from FIG. 8.

FIG. 11 is a block diagram showing a configuration of a semiconductor device analyzer according to a second exemplary embodiment of the present invention.

FIG. 12 is a drawing for describing an outline of a die database test of Patent Document 1, outlined according to an analysis based on the view of the present invention.

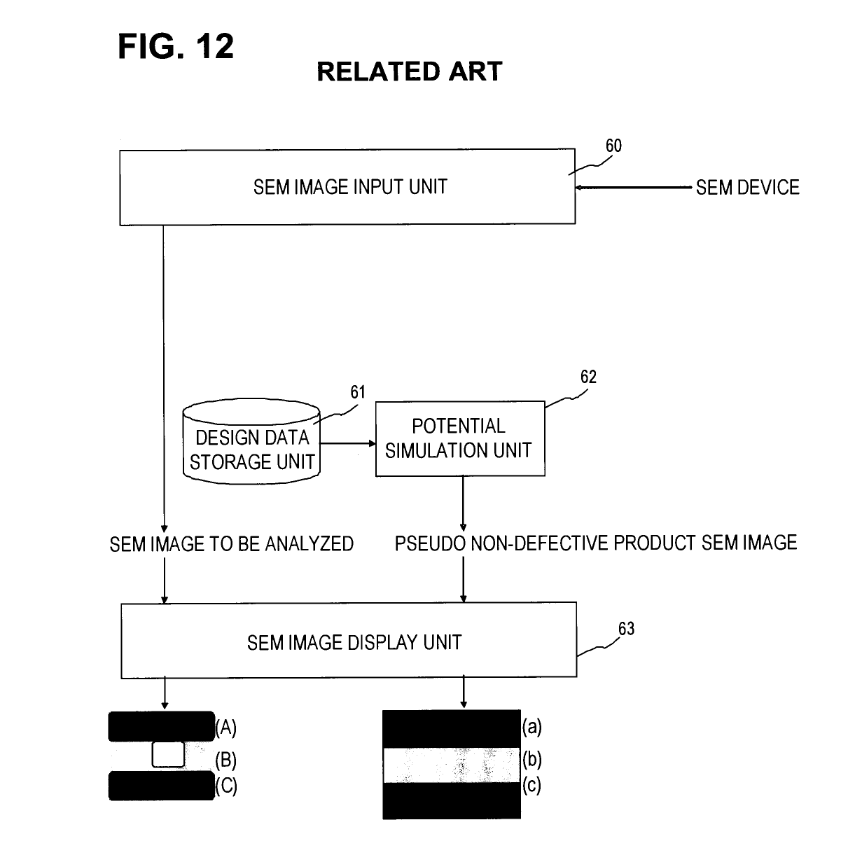

### PREFERRED MODES

A detailed description will now be given concerning preferred embodiments for implementing the present invention, making reference to the drawings.

### First Exemplary Embodiment

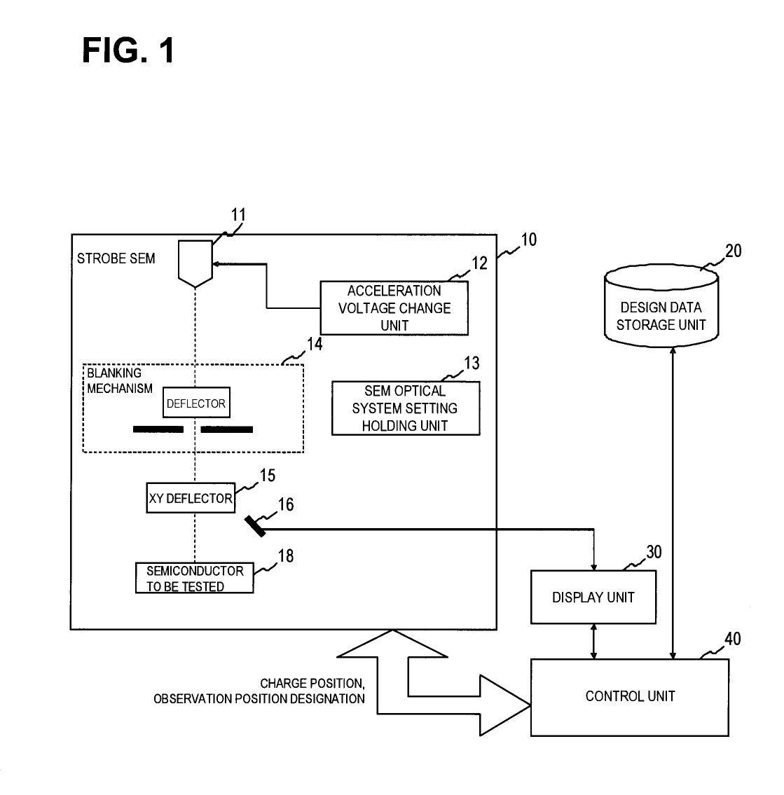

FIG. 1 is a block diagram showing a configuration of a semiconductor device analyzer according to a first exemplary embodiment of the present invention.

Referring to FIG. 1, the semiconductor device analyzer according to the first exemplary embodiment of the present invention, in outline, is configured to include a strobe SEM 10, a design data storage unit 20 that stores design data (CAD data, layout data) such as semiconductor device wiring information and the like, a display unit 30 configured by a display device displaying a secondary electron image outputted by the strobe SEM 10, and a control unit 40 configured by a computer that controls these units.

The strobe SEM 10 is configured to include an electron beam radiation unit (electron gun) 11 that radiates a primary electron beam to a semiconductor (device) 18 that is to be tested, an acceleration voltage change unit 12 that changes acceleration voltage with respect to the electron beam radiation unit 11, a SEM optical system setting holding unit 13 that holds information for controlling a blanking mechanism 14 and an XY deflector 15, the blanking mechanism 14, the XY deflector 15, and a secondary electron detector 16.

The blanking mechanism 14 is configured by a blanking deflector and an aperture (blanking plate), and performs blanking of an electron beam radiated from the electron beam radiation unit (electron gun) 11, by a blanking pulse based on a radiation pattern indicated by the control unit 40.

The control unit 40 reads design data of the semiconductor (device) 18 to be tested, from the design data storage unit 20, displays data on the display unit 30, and receives an instruction concerning a charge injection location or an observation location from a user. When the instruction concerning the charge injection location or the observation location is inputted by the user, the control unit 40 uses the design data of the design data storage unit 20 to generate a radiation pattern (typically of spot-like pattern) corresponding to the inputted charge injection location (or spot) or the observation location (or site). Next, the control unit 40, holding a parameter for realizing a generated radiation pattern in the SEM optical system setting holding unit 13, instructs the strobe SEM 10 to radiate according to the radiation pattern. It is to be noted that, instead of the design data of the semiconductor (device) 18 to be tested, a radiation pattern (typically of a spot-line pattern) may be created that injects charge at an arbitrary location of the semiconductor (device) 18 to be tested, based on an image of the semiconductor (device) 18 to be tested obtained by the secondary electron detector 16.

Here, a pattern for radiating a location (position, depth) group where a charge is injected to the semiconductor (device) 18 to be tested by the user is termed as a first radiation pattern, and a location (position, depth) group where an effect due to the injection of the charge is observed is termed as a second radiation pattern. Since parameters for realizing these two radiation patterns are held in the SEM optical system setting holding unit 13, after radiation according to the first radiation pattern, observation according to the second radiation pattern promptly becomes possible.

Continuing, a detailed description is given concerning defect detection flow for the semiconductor (device) 18 to be tested using the abovementioned semiconductor device analyzer, making reference to the drawings.

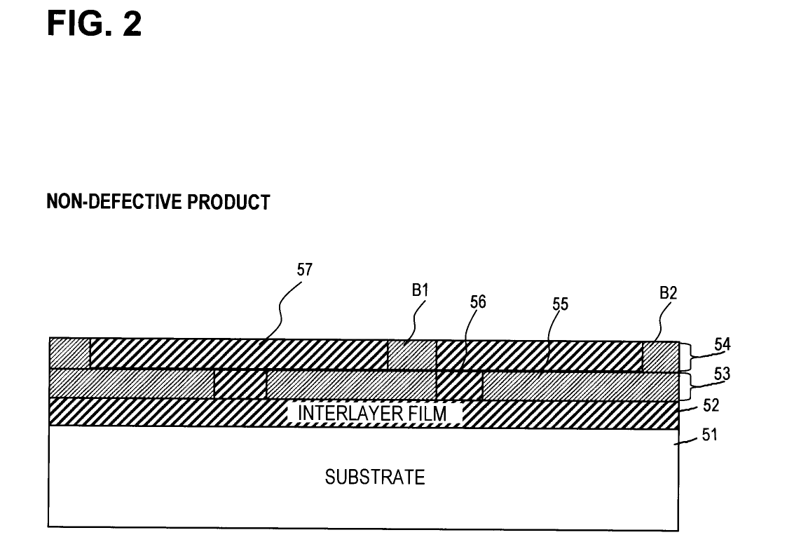

FIG. 2 to FIG. 5 are drawings schematically showing the semiconductor (device) 18 to be tested after polishing or during processing. The semiconductor (device) 18 to be tested of FIG. 2 to FIG. 5 is a non-defective product case; an interlayer film 52 is formed on top of a substrate 51, and thereon a wiring layer 53 and an insulating layer 54 are additionally formed. Wiring 55 and an insulating film 56 are formed on the wiring layer 53, and vias B1 and B2, and an insulating film 57 are formed on the insulating layer 54. Here, consideration is given to detection of whether or not a short or an open (break) occurs in the vias B1 and B2 of FIG. 2.

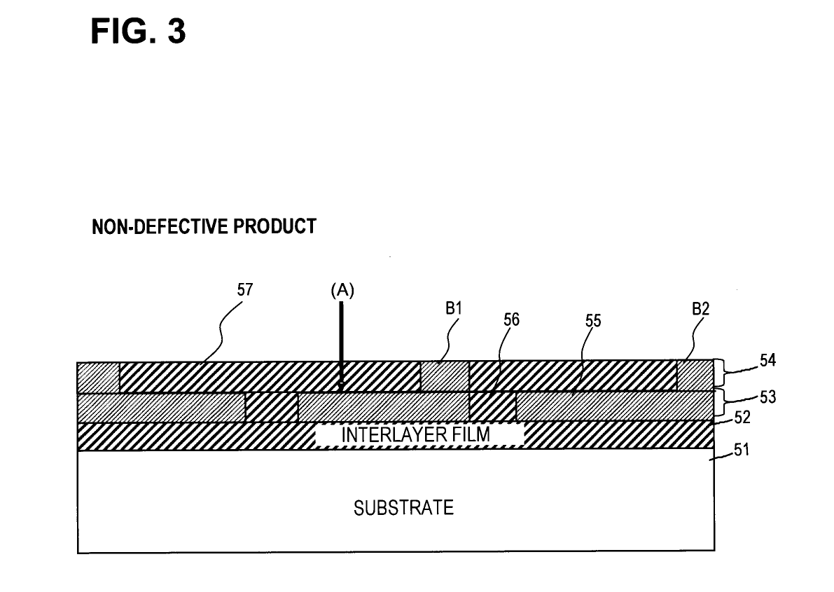

FIG. 3 shows a charge injection location (A) according to the first radiation pattern. The charge injection location (A) is wiring connected to the via B1, and is not connected to the via B2. Furthermore, the charge injection location (A) is at a layer lower than the insulating layer 54, and charge is injected at an acceleration voltage higher than that at which charge is injected to the insulating layer 54 (refer to Patent Document 4, the disclosure thereof being incorporated herein by references thereto).

The charge injected according to the first radiation pattern spreads to equipotential wiring or a shorted location electrostatically, and is held with a time scale of seconds or greater.

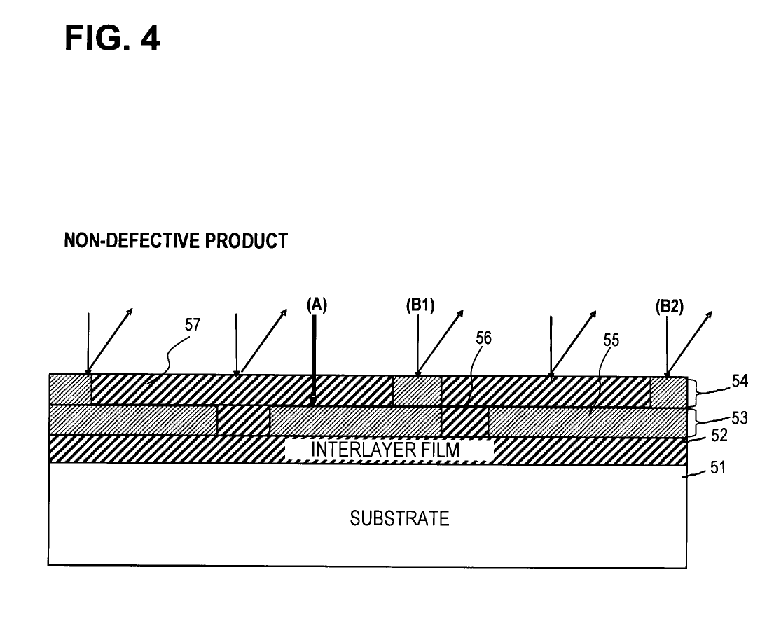

FIG. 4 shows observation locations according to the second radiation pattern that is promptly implemented after radiation according to the first radiation pattern. For example, by observing the charge state of the via (B1) and the via (B2), it is possible to detect whether or not a defect has occurred in the via (B1) or the via (B2). Here, since the semiconductor (device) 18 under testing is a non-defective product, charge-up is observed at the via (B1), and charge-up is not observed at the via (B2).

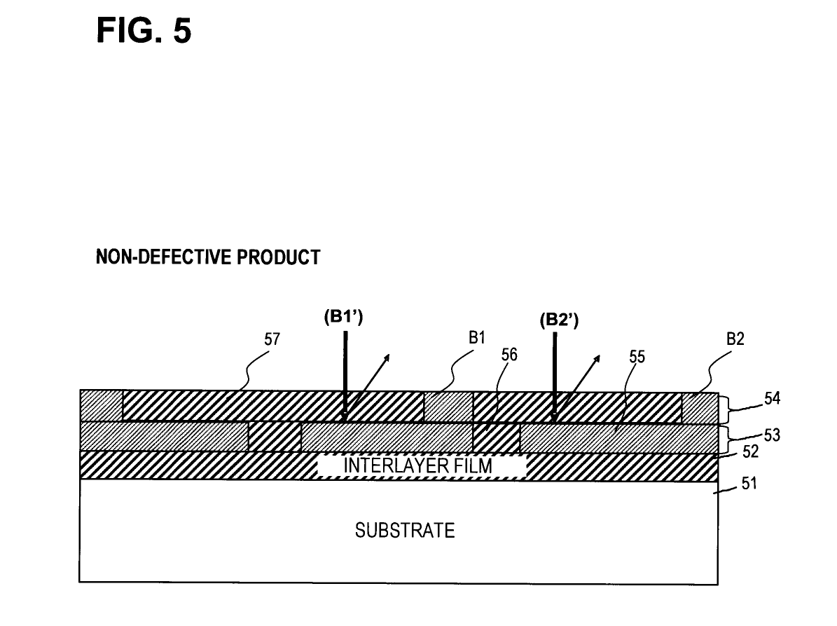

FIG. 5 shows observation locations according to a radiation pattern that is different from the second radiation pattern of FIG. 4. An observation location (B1′) according to the second radiation pattern is identical to the charge injection location (A). With this radiation pattern, by observing a charge state of the via B1 and the via B2, it is possible to detect whether or not a defect has occurred at the via B1 or the via B2. Here, since the semiconductor (device) 18 under testing is a non-defective product, charge-up is observed at the via (B1′), and charge-up is not observed at a via (B2′).

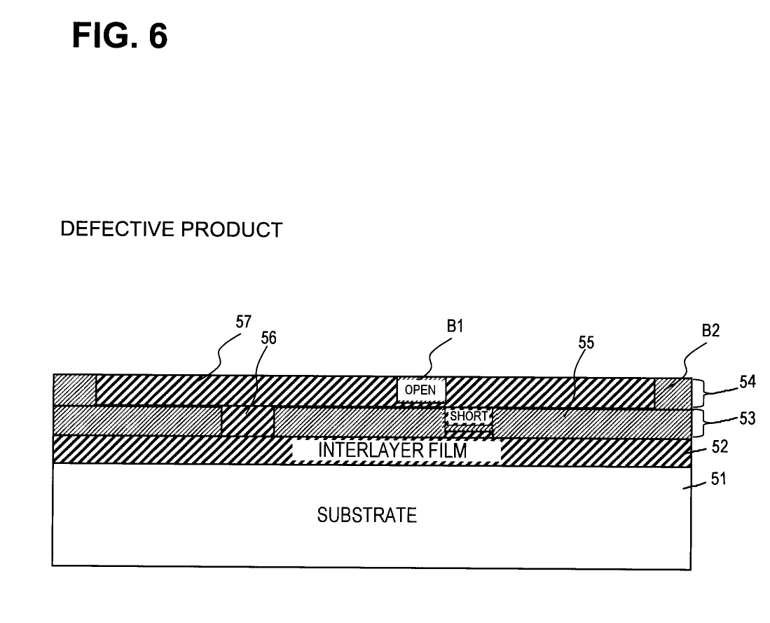

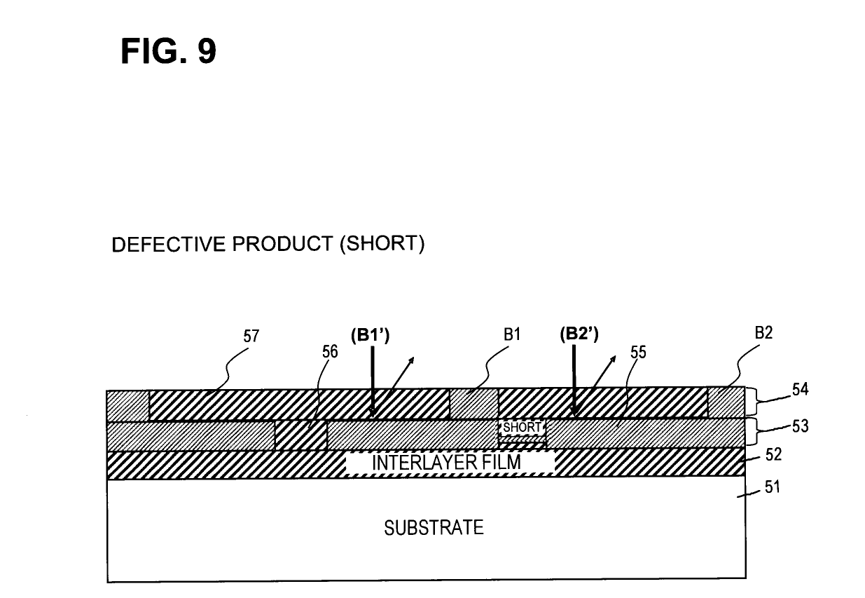

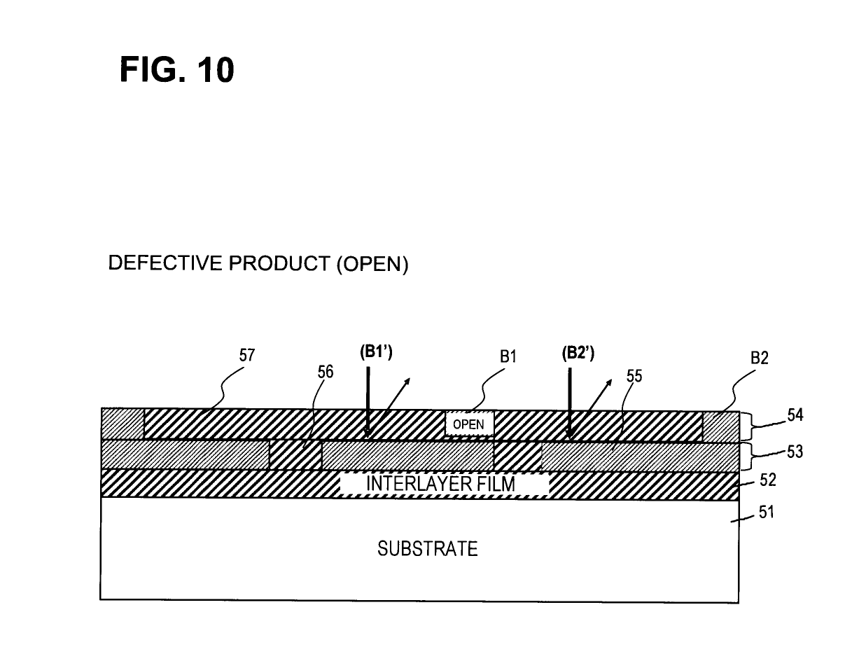

FIG. 6 to FIG. 10 are drawings for describing defect detection flow of the semiconductor (device) 18 to be tested in which there is a defect location. In the semiconductor (device) 18 to be tested in FIG. 6 to FIG. 8, an open defect occurs at the via B1, and a short defect occurs between adjacent wiring layers connected to the via B1 in the wiring layer 53 connected to the via B2. In the semiconductor (device) 18 to be tested, in FIG. 9, a short defect occurs in the wiring layer connect to the via B2, and in the semiconductor (device) 18 to be tested, in FIG. 10, an open defect occurs at the via B1. Consideration is given below concerning detecting these.

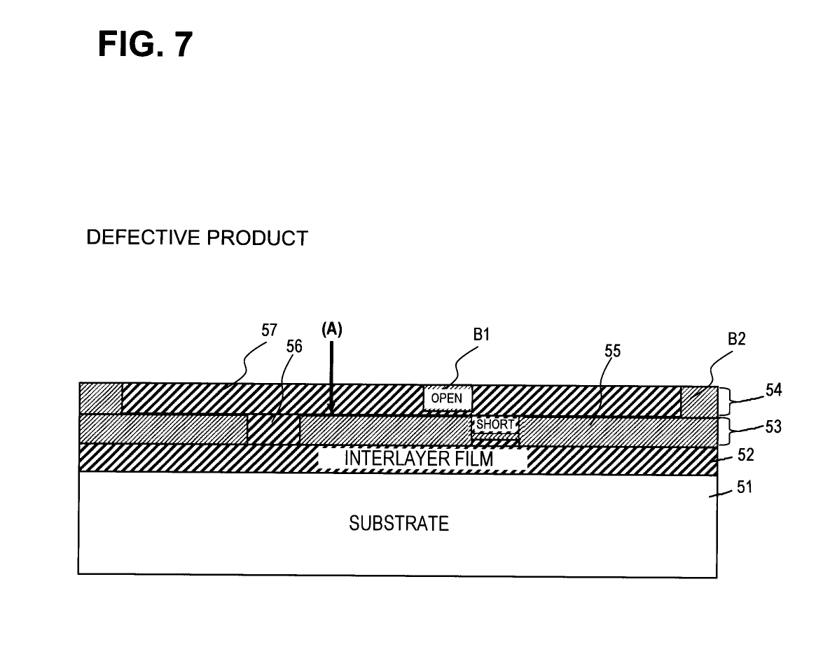

FIG. 7 shows a charge injection location (A) according to the first radiation pattern. The charge injection location (A) of FIG. 7 is identical to the charge injection location (A) in the case where the non-defective product of FIG. 3 is under consideration.

The charge injected according to the first radiation pattern spreads to equipotential wiring or a short location electrostatically, and is held with a time scale of seconds or greater. In the example of FIG. 7, since an open defect occurs at via B1, and a short defect occurs in the wiring layer connected to the via B2, the charge injected at the charge injection location (A) cannot move as far as the via B1, however, on the one hand, spreads through the short location as far as the via B2.

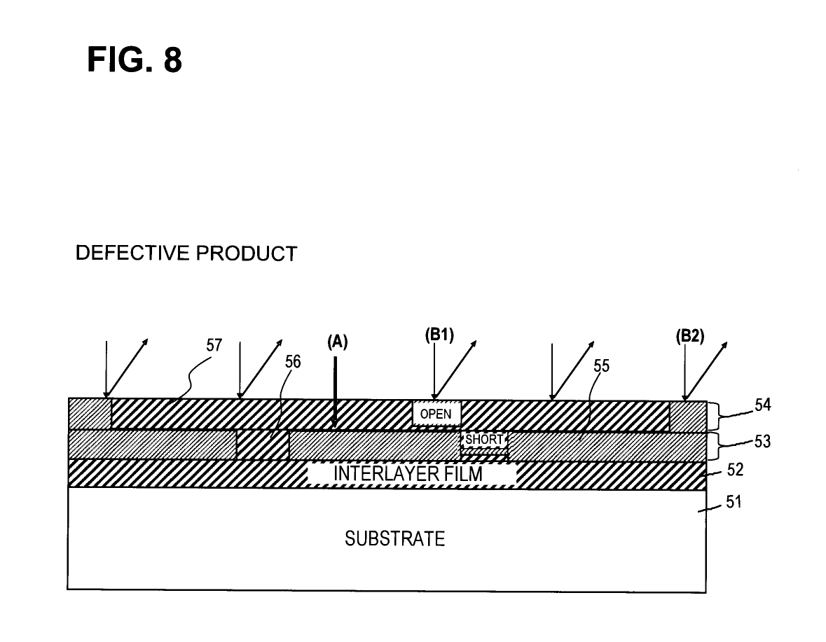

FIG. 8 shows observation locations according to the second radiation pattern that is the same as FIG. 4. For example, by observing a charge state of the via (B1) and the via (B2), it is possible to detect whether or not a defect has occurred in the via (B1) or the via (B2). In the example of FIG. 8, since it is not possible to observe charge-up at the via (B1) where charge-up should be observed, it is possible to confirm that an open defect has occurred in the vicinity of the via (B1). Furthermore, since charge-up has been observed at the via (B2) where charge-up should not be observed, it is possible to confirm that a short defect has occurred in the vicinity of the via (B2).

FIG. 9 shows observation locations according to the second radiation pattern that is the same as FIG. 5. For this radiation pattern also, by observing charge states of an observation location (B1′) and an observation location (B2′), it is possible to detect whether or not an open or a short defect has occurred. Since, in the semiconductor (device) 18 to be tested, in FIG. 9, only a short defect has occurred, at the observation location (B1′), due to an effect of the short a secondary electron image (accumulation of charge is small) that is darker than a charge-up state in the non-defective product of FIG. 5 is obtained, so that it is possible to confirm that a short defect has occurred in the vicinity of the observation location (B1′). Furthermore, at the observation location (B2′), due to a short effect, charge-up or a bright secondary electron image (accumulation of charge is recognized) is observed, so that it is possible to confirm that a short defect has occurred in the vicinity of the observation location (B2′).

FIG. 10 shows a case of the semiconductor (device) 18 to be tested where only an open defect has occurred. In this case also, at the observation location (B1′), due to an effect of the open, with injected charge less than that for the non-defective product of FIG. 5, charge-up or a bright secondary electron image is observed, so that it is possible to confirm that an open defect has occurred in the vicinity of the observation location (B1′).

In this way, the two radiation patterns (as described in FIG. 5, FIG. 9, and FIG. 10, the two may be patterns in which at least a part of the charge injection locations is an observation location) are separately used, and at a group of locations at which it is desired to observe presence or absence of either an open or a short, or of both an open and a short, by injecting a charge with the first radiation pattern and comparing with an observation with the second radiation pattern or non-defective product data, it is possible to easily identify a defect location.

Furthermore, in the abovementioned exemplary embodiment a description has been given in which, with the second radiation pattern, a charge accumulation state is observed in a wiring layer of a stratum the same as the charge injection location or an upper layer, but the charge injection location (or spot) and the observation location (or site) can be freely set in accordance with a defect mode that is desired to be detected (expected). For example, charge may be injected at an arbitrary location (position, depth) in accordance with the first radiation pattern, and the charge accumulation state may be observed in a wiring layer above the layer into which the charge is injected, according to the second radiation pattern.

Furthermore, as described in FIG. 9 and FIG. 10, since the defect location appears as a change in potential intensity detected according to the second radiation pattern, visual comparison by an observer is clearly possible, and by the control unit 40 it is possible to perform automated detection of a defect location by comparison of detected potential intensity with a non-defective product as a target, or to perform difference image generation of a potential intensity image. Furthermore, it is effective to compare a result of observation in a case where the injection of a charge according to the first radiation pattern is performed, and a result of observation in a case where radiation is performed by a third radiation pattern in which a charge injection location is different from the first radiation pattern. In this way, it is possible to easily observe a change in the charge accumulation state by changing the charge injection location(s).

### Second Exemplary Embodiment

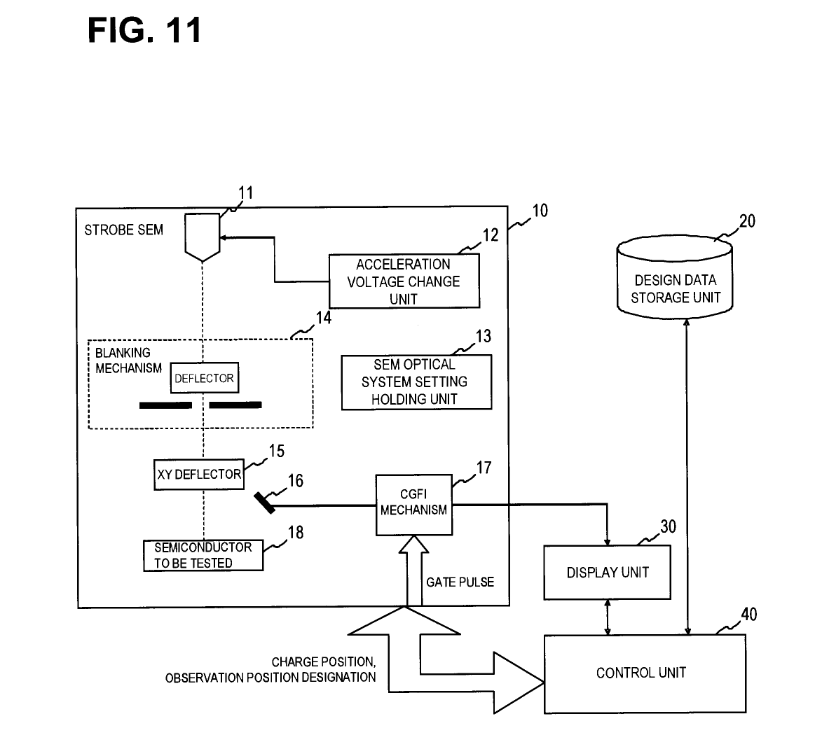

Next, a detailed description will be given concerning a second exemplary embodiment of the present invention, making reference to the drawings. FIG. 11 is a block diagram showing a configuration of a semiconductor device analyzer according to the second exemplary embodiment of the present invention. A point of difference between the present exemplary embodiment and the configuration of the first exemplary embodiment described above is that a CGFI mechanism 17 is provided between a second electron detector 16 and a display unit 30.

The CGFI mechanism 17 is a means for realizing observation by a CGFI (Continuous Gated Fault Imaging) method that performs image signal input limitation on the display unit 30 side, based on a gate pulse generated by a gate pulse generator, which is omitted from the drawings. Therefore, in the present exemplary embodiment, an observation according to the second radiation pattern is realized by radiating (scanning) a primary electron beam on the entire surface of the semiconductor (device) 18 to be tested, and invalidating image data outside of a target of observation by a gate pulse.

According to the present exemplary embodiment, it is possible to easily identify a defective location in a semiconductor device that is to be analyzed, in the same way as in the first exemplary embodiment described above.

A preferred exemplary embodiment of the present invention has been described above, but the present invention is not limited to the abovementioned exemplary embodiments, and further modifications, substitutions, and adjustments can be added within a scope that does not depart from a fundamental technological concept of the invention. For example, in the abovementioned exemplary embodiments a description has been given using a strobe SEM device, but it is also possible to use a test device or the like for a semiconductor device having a similar mechanism. Furthermore, there is no limitation to an electron beam, and it is also possible to use a charged particle beam.

Furthermore, it is also possible to add a charge elimination process using technology described in Patent Documents 5 or 6, radiation such as an electron shower, an ion shower, ultra-violet rays, soft X-rays, a rays, or the like, or exposure to a charge elimination atmosphere. For example, in a case of using technology described in Patent Documents 5 and 6, as a result of radiating the charged particle beam according to a prescribed radiation pattern (a fourth radiation pattern) after observation according to the second radiation pattern, and performing charge elimination, it is possible to detect a defect according to whether or not charge elimination is performed as expected. For example, it is possible to have a pattern having the entire surface of the semiconductor (device) 18 to be tested as a target for charge elimination, or a pattern including in the charge elimination location a charge injection location according to the first and second radiation patterns, or at least a part of the observation locations. The entire disclosures of Patent Document 5 and 6 are incorporated herein by reference thereto.

A description has been given in which observation is performed according to the second radiation pattern after the injection of charge according to the first radiation pattern, but it is possible to use a radiation pattern such that both injection of the above-mentioned charge and the observation may be performed, according to the charge injection location and observation location of the semiconductor (device) 18 to be tested.

The radiation pattern may be adapted to the dimension (size) of the structure of the device, e.g., wiring (width, depth and length), and may be typically of a spot-like configuration depending on the structure of the semiconductor device, including the active or passive elements of the device, particularly with respect to the wiring. It is understood that the first radiation pattern or the second radiation pattern may be formulated by scanning.

In the present invention there are possible modes as follows.

Mode 1. As set forth in the first aspect.
Mode 2. The semiconductor device analyzer according to mode 1, wherein said semiconductor device analyzer performs radiation of a charged particle beam according to a second radiation pattern in order to observe said charge accumulation state.
Mode 3. The semiconductor device analyzer according to mode 1 or 2, wherein said charged particle beam is selectively radiated using a blanking mechanism.
Mode 4. The semiconductor device analyzer according to any one of modes 1 to 3, wherein an acceleration voltage when radiating according to said first radiation pattern, and an acceleration voltage when radiating according to said second radiation pattern are variable.
Mode 5. The semiconductor device analyzer according to any one of modes 1 to 4, further comprising a setting holding unit that holds a parameter that realizes said radiation patterns.
Mode 6. The semiconductor device analyzer according to any one of modes 1 to 5, wherein an open or a short in a wiring system can be detected by comparing a charge accumulation state brought about by injecting a charge according to said first radiation pattern, and said observed charge accumulation state.
Mode 7. The semiconductor device analyzer according to any one of modes 1 to 5, wherein an open or a short in a wiring system can be detected by comparing a charge accumulation state observed by injecting a charge according to said first radiation pattern and a charge accumulation state observed by injecting a charge according to a third radiation pattern having a charge injection location that is different from said first radiation pattern.
Mode 8. The semiconductor device analyzer according to any one of modes 1 to 7, further comprising:

a unit that performs charge elimination in said semiconductor device that is to be analyzed, wherein

a charge accumulation state in said semiconductor device that is to be analyzed can be observed once again.

Mode 9. The semiconductor device analyzer according to mode 8, wherein an open or a short in a wiring system can be detected by comparing a charge accumulation state brought about by said charge elimination, and said observed charge accumulation state.
Mode 10. The semiconductor device analyzer according to any one of modes 6, 7, and 9, further comprising an unit that outputs a result of comparing said charge accumulation states as a difference image.
Mode 11. The semiconductor device analyzer according to any one of modes 6, 7, and 9, further comprising a unit that automatically judges presence or absence of a defect, based on a result of comparing said charge accumulation states.
Mode 12. A semiconductor device analysis method as set forth as the second aspect.
Mode 13. The semiconductor device analysis method according to mode 12, comprising radiating a charged electron beam according to a second radiation pattern, in order to observe a charge accumulation state of said semiconductor device that is to be analyzed.
Mode 14. The semiconductor device analysis method according to mode 12 or 13, comprising selectively radiating said charged electron beam using a blanking mechanism.
Mode 15. The semiconductor device analysis method according to any one of modes 12 to 14, wherein an acceleration voltage when radiating according to said first radiation pattern, and an acceleration voltage when radiating according to said second radiation pattern are variable.
Mode 16. The semiconductor device analysis method according to any one of modes 13 to 15, further comprising:

holding a parameter that realizes said first and said second radiation patterns in a prescribed storage unit, wherein

after injecting a charge according to said first radiation pattern, said parameter is read to execute observation of radiation according to said second radiation pattern and a charge state.

Mode 17. The semiconductor device analysis method according to any one of modes 12 to 16, comprising setting a radiation pattern so as to enable detection of an open or a short in a wiring system, by comparing a charge accumulation state brought about by injecting charge according to said first radiation pattern, and said observed charge accumulation state.
Mode 18. The semiconductor device analysis method according to any one of modes 12 to 16, comprising setting a radiation pattern so as to enable detection of an open or a short in a wiring system, by comparing a charge accumulation state brought about by injecting a charge according to said first radiation pattern and a charge accumulation state observed by injecting a charge according to a third radiation pattern having a charge injection location that is different from said first radiation pattern.
Mode 19. The semiconductor device analysis method according to any one of modes 12 to 17, comprising:

after performing charge elimination in said semiconductor device that is to be analyzed,

implementing observation once again of a charge accumulation state in said semiconductor device that is to be analyzed.

Mode 20. The semiconductor device analysis method according to mode 19, comprising enabling detection of an open or a short in a wiring system, by comparing a charge accumulation state brought about by said charge elimination, and said observed charge accumulation state.

Mode 21. The semiconductor device analysis method according to any one of modes 17, 18, and 20, further comprising outputting a result of comparing said charge accumulation states as a difference image.

Mode 22. The semiconductor device analysis method according to any one of modes 17, 18, and 20, further comprising automatically judging presence or absence of a defect, based on a result of comparing said charge accumulation states.

It should be noted that other objects, features and aspects of the present invention will become apparent in the entire disclosure and that modifications may be done without departing the gist and scope of the present invention as disclosed herein and claimed as appended herewith. Also it should be noted that any combination of the disclosed and/or claimed elements, matters and/or items may fall under the modifications aforementioned.

What is claimed is:

1. A semiconductor device analyzer that radiates a charged particle beam on a sample and displays a secondary electron image according to detected secondary electron intensity, said analyzer comprising:
a unit that radiates a charged particle beam according to a first radiation pattern by which a charge is injected at a prescribed location of a semiconductor device that is to be analyzed, and injects the charge, and
a unit that observes a charge accumulation state of said semiconductor device that is to be analyzed.

2. The semiconductor device analyzer according to claim 1, wherein said semiconductor device analyzer performs radiation of a charged particle beam according to a second radiation pattern in order to observe said charge accumulation state.

3. The semiconductor device analyzer according to claim 1, wherein an acceleration voltage when radiating according to said first radiation pattern, and an acceleration voltage when radiating according to said second radiation pattern are variable.

4. The semiconductor device analyzer according to claim 1, further comprising a setting holding unit that holds a parameter that realizes said radiation patterns.

5. The semiconductor device analyzer according to claim 1, wherein an open or a short in a wiring system can be detected by comparing a charge accumulation state brought about by injecting a charge according to said first radiation pattern, and said observed charge accumulation state.

6. The semiconductor device analyzer according to claim 1, wherein an open or a short in a wiring system can be detected by comparing a charge accumulation state observed by injecting a charge according to said first radiation pattern and a charge accumulation state observed by injecting a charge according to a third radiation pattern having a charge injection location that is different from said first radiation pattern.

7. The semiconductor device analyzer according to claim 1, further comprising:
a unit that performs charge elimination in said semiconductor device that is to be analyzed, wherein
a charge accumulation state in said semiconductor device that is to be analyzed can be observed once again.

8. The semiconductor device analyzer according to claim 7, wherein an open or a short in a wiring system can be detected by comparing a charge accumulation state brought about by said charge elimination, and said observed charge accumulation state.

9. The semiconductor device analyzer according to claim 5, further comprising an unit that outputs a result of comparing said charge accumulation states as a difference image.

10. The semiconductor device analyzer according to claim 5, further comprising a unit that automatically judges presence or absence of a defect, based on a result of comparing said charge accumulation states.

11. A semiconductor device analysis method that uses a semiconductor device analyzer, which radiates a charged particle beam on a sample and displays a secondary electron image according to detected secondary electron intensity, said method comprising:
injecting a charge by radiating a charged particle beam according to a first radiation pattern by which a charge is injected at a prescribed location of a semiconductor device that is to be analyzed, and
observing a charge accumulation state of said semiconductor device that is to be analyzed.

12. The semiconductor device analysis method according to claim 11, comprising radiating a charged electron beam according to a second radiation pattern, in order to observe a charge accumulation state of said semiconductor device that is to be analyzed.

13. The semiconductor device analysis method according to claim 11, wherein an acceleration voltage when radiating according to said first radiation pattern, and an acceleration voltage when radiating according to said second radiation pattern are variable.

14. The semiconductor device analysis method according to claim 12, further comprising:
holding a parameter that realizes said first and said second radiation patterns in a prescribed storage unit, wherein
after injecting a charge according to said first radiation pattern, said parameter is read to execute observation of radiation according to said second radiation pattern and a charge state.

15. The semiconductor device analysis method according to claim 11, comprising setting a radiation pattern so as to enable detection of an open or a short in a wiring system, by comparing a charge accumulation state brought about by injecting charge according to said first radiation pattern, and said observed charge accumulation state.

16. The semiconductor device analysis method according to claim 11, comprising setting a radiation pattern so as to enable detection of an open or a short in a wiring system, by comparing a charge accumulation state brought about by injecting a charge according to said first radiation pattern and a charge accumulation state observed by injecting a charge according to a third radiation pattern having a charge injection location that is different from said first radiation pattern.

17. The semiconductor device analysis method according to claim 11, comprising:
after performing charge elimination in said semiconductor device that is to be analyzed,
implementing observation once again of a charge accumulation state in said semiconductor device that is to be analyzed.

18. The semiconductor device analysis method according to claim 17, comprising enabling detection of an open or a short in a wiring system, by comparing a charge accumulation state brought about by said charge elimination, and said observed charge accumulation state.

19. The semiconductor device analysis method according to claim 15, further comprising outputting a result of comparing said charge accumulation states as a difference image.

20. The semiconductor device analysis method according to claim 15, further comprising automatically judging presence or absence of a defect, based on a result of comparing said charge accumulation states.
